(19) United States
(12) Patent Application Publication
(10) Pub. No.: US 2002/0027291 A1
(43) Pub. Date: Mar. 7, 2002

(54) SEMICONDUCTOR DEVICE FOR PREVENTING CORROSION OF METALLIC FEATUES

(76) Inventor: TAKASHI YOKOYAMA, TOKYO (JP)

Correspondence Address: SUGHRUE MION ZINN MACPEAK & SEAS, 2100 PENNSYLVANIA AVENUE NW, WASHINGTON, DC, 20037

(21) Appl. No.: 09/299,569

(22) Filed: Apr. 27, 1999

(30) Foreign Application Priority Data
Apr. 30, 1998 (JP) 121174/1998

(51) Int. Cl. H01L 23/48; H01L 23/52; H01L 29/40

(52) U.S. Cl. 257/773

(57) ABSTRACT

A semiconductor device and a manufacturing method thereof which enable corrosion of an Al-wiring to be prevented in the case where insulating film containing fluorine is in use. Al-wiring is formed on a silicon substrate, while etching Aluminum with photoresist as a mask. In this process, a natural oxide film is formed on side wall of the Al-wiring. There is eliminated the natural oxide film by physical etching due to inert gas such as argon and so forth or reactive etching such as BCl₃ and so forth under atmosphere of reduced pressure or a few existence of oxygen. In succession, there is formed high quality aluminum oxide film 6a on the Al-side wall, while introducing oxygen or oxygen radical in a state of not breaking a vacuum. There is formed a fluorine contained interlayer insulating film 7 on a barrier of high quality aluminum oxide film 6a.

### BACKGROUND OF THE INVENTION

The present invention relates to a semiconductor device and manufacturing method thereof More to particularly, this invention relates to a semiconductor device which is suitable for use in LSI (Large Scale Integration) and so forth, and which has aluminum wiring and interlayer insulating film including fluorine.

### DESCRIPTION OF THE PRIOR ART

Formerly, an object for accelerating signal processing of LSI is achieved by the fact that it causes the mask pattern design rule (design rule) to be miniaturized in order to improve the operation speed of the transistor. However, the miniaturization of the design rule causes signal delay in conjunction with wiring to affect largely to operation speed of the transistor. There are listed resistance value of the wiring and parasitic capacitance of interlayer insulating film by way of primary factor of signal delay in the wiring. Capacitance between wiring is greatly increasing because wiring pitch becomes narrow accompanying with miniaturization of the design rule. Further, aspect ratio of the wiring is increased because miniaturization rate of wiring height is small as compared with miniaturization of wiring width in order to avoid increase of resistance value of wiring, thus having a tendency to promote increase of capacitance between the wiring.

Investigation of utilizing an interlayer insulating film with low dielectric constant instead of conventional silicone oxide film is implemented actively by way of method for preventing increase of capacitance of the interlayer insulating film. Fluorine contained silicon oxide film which has Si—F bonding that fluorine is added in silicon oxide film by plasma CVD method, is capable of being reduced a relative dielectric constant from 4.0 to 4.4 of conventional silicon oxide film to degree of 3.3 to 3.9. This is disclosed in the Japanese Patent Application Laid-Open No. HEI 7-74245.

Further, the fluorine contained silicon oxide film has superior covering property of difference in level (insulating film can lay wiring therein smoothly) in comparison with the silicon oxide film. The Japanese Patent Application Laid-Open No. HEI 6-302593 discloses relevant technique by way of embedding technique of insulating film between fine wiring.

However, according to the above described conventional example, the fluorine which is added in order to reduce relative dielectric constant or to improve embedding property is possible to corrode aluminum wiring, while interacting with aluminum. Particularly, in cases where the relative dielectric constant is reduced largely, or the embedding property is improved drastically, since it is necessary to increase fluorine content within the silicon oxide film, a great deal of fluorine is contained in the film. In this case, there is a problem that in the fluorine existing in the film of the state as being not combined to the silicon or in the fluorine of the state as being combined to the silicon, the fluorine is left in the manufacturing process of tungsten CVD and so forth where heat is added. It is possible to corrode wiring because the fluorine diffuses to aluminum wiring.

There is described using model shown in FIG. 1, about the conventional case that the aluminum wiring and the fluorine contained silicon oxide film are used. There is formed an aluminum wiring on a silicon substrate on which transistors and so forth are formed. Generally, the aluminum wiring has junction metal of TiN/Ti and so forth at under layer, and reflection avoidance film of TiN and so forth for avoiding reflection at the time of lithography at upper layer. In succession, there is formed silicon oxide film containing fluorine on the aluminum wiring by plasma CVD method. In this constitution, it is concerned about corrosion of the aluminum wiring because side face of the aluminum wiring is contacted with SiOF film directly.

### SUMMARY OF THE INVENTION

In view of the foregoing, it is an object of the present invention, in order to overcome the above-mentioned problems, to provide a semiconductor device and manufacturing method thereof which enable corrosion of the aluminum wiring to be prevented in the case where there is used insulating film containing fluorine.

According to a first aspect of the present invention, in order to achieve the above-mentioned object, there is provided a semiconductor device which uses metal in which aluminum is regarded to be main component for the sake of wiring, and uses fluorine contained insulating film for the sake of interlayer insulating film, wherein a portion of the Al-wiring which is contacted with the fluorine contained insulating film is covered with aluminum oxide film.

According to a second aspect of the present invention, in the first aspect, there is provided a semiconductor device, wherein film thickness of the aluminum oxide film is thickened more than 3 nm and film thickness of the aluminum oxide is thinned less than 10 nm.

According to a third aspect of the present invention, in the first aspect, there is provided a semiconductor device, wherein there is used any one of a fluorine contained silicon oxide film, fluorine contained carbon resin, fluorine contained silicon carbon resin, and fluorine polyimide within which fluorine of fluorine concentration less than 10 atom % is contained by way of the fluorine contained insulating film.

According to a fourth aspect of the present invention, there is provided a manufacturing method of a semiconductor device which comprises the processes of a process for providing metal whose main component is aluminum on semiconductor substrate, a process for forming wiring, while etching the metal, a process for eliminating natural oxide film which is formed on side wall of the wiring, a process for forming aluminum oxide film on the side wall of the wiring from which the natural oxide film is eliminated, and a process for forming interlayer insulating film in which fluorine contained insulating film is used.

According to a fifth aspect of the present invention, there is provided a manufacturing method of a semiconductor device which comprises the processes of a process for providing metal whose main component is aluminum on semiconductor substrate, a process for etching silicon oxide film, while forming the silicon oxide film on the metal, a process for forming wiring, while etching the metal with the etched silicon oxide film as a mask, a process for eliminating natural oxide film which is formed on side wall of the wiring, a process for forming aluminum oxide film on the side wall of the wiring from which the natural oxide film is eliminated, and a process for forming interlayer insulating film using fluorine contained insulating film.

According to a sixth aspect of the present invention, in the fourth or fifth aspect, there is provided a manufacturing method of a semiconductor device, wherein, by way of eliminating method of the natural oxide film and forming method of the aluminum oxide film, the eliminating method eliminates natural oxide film from surface of the metal by plasma from inert gas such as argon and so forth at reduced pressure, before the forming method implements plasma processing, while introducing gas containing either oxygen or ozone, thus forming the aluminum oxide film with uniform film property.

According to a seventh aspect of the present invention, in the fourth or fifth aspect, there is provided a manufacturing method of a semiconductor device, wherein film thickness of the aluminum oxide film is thickened more than 3nm and film thickness of the aluminum oxide is thinned less than 10 nm.

According to an eighth aspect of the present invention, in the fourth or fifth aspect, there is provided a manufacturing method of a semiconductor device, wherein there is used any one of a fluorine contained silicon oxide film, fluorine contained carbon resin, fluorine contained silicon carbon resin, and fluorine polyimide within which fluorine of fluorine concentration less than 10 atom % is contained by way of said fluorine contained insulating film.

The above and further objects and novel features of the invention will be more fully understood from the following detailed description when the same is read in connection with the accompanying drawings. It should be expressly understood, however, that the drawings are for purpose of illustration only and are not intended as a definition of the limits of the invention.

### BRIEF DESCRIPTION OF THE DRAWINGS

FIG. 1 is a constitutional view showing model for explaining conventional semiconductor device;

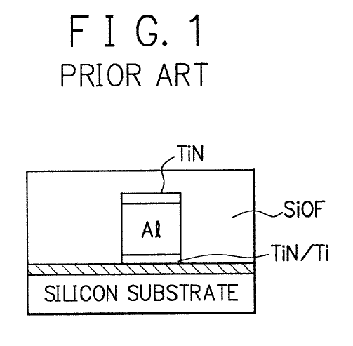

FIG. 2A to 2E are sectional views showing manufacturing method of the semiconductor device according to a first embodiment of the present invention;

FIG. 3 is a constitutional view using calculation of capacitance variation between Aluminum wiring in the semiconductor device of the present invention;

FIGS. 4A and 4B are characteristic views showing relationship between film thickness of aluminum oxide and capacitance between Aluminum wiring;

FIG. 5 is a table showing relationship between fluorine concentration and wiring reliability; and

FIG. 6A to 6E are sectional views showing manufacturing method of the semiconductor device according to a second embodiment of the present invention.

### DETAILED DESCRIPTION OF THE PREFERRED EMBODIMENT

A preferred embodiment of the present invention will be described in detail in accordance with the accompanying drawings.

A large characteristic in the embodiment of the present invention is to form a film with corrosion-resistant to the fluorine, while forming a high quality aluminum oxide film at a portion of Al-wiring (aluminum wiring), which is contacted with an insulating film containing the fluorine.

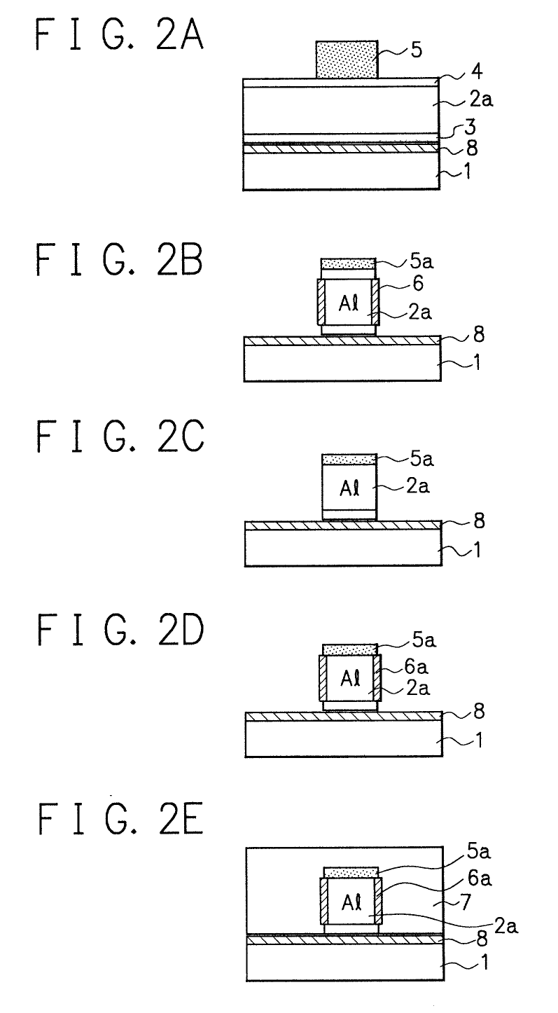

There will be described an outline of characteristic of the first embodiment of the present invention referring to FIG. 2A to 2E.

There is provided an Aluminum 2 on the silicon substrate 1 with a photoresist 5 as a mask. The Aluminum 2 is etched in order to form an Al-wiring 2a shown in FIGS. 2A and 2B. In this manufacturing process, a natural oxide film 6 is formed on a side wall portion of the Al-wiring 2a of FIG. 2B. The natural oxide film 6 is formed on the Al-wiring at the same time an Aluminum etching is implemented. Chlorine gas during the etching and elements such as carbon and so forth in the photoresist material are entrapped in the aluminum oxide. Thus there is not formed a high quality aluminum oxide film with uniform composition.

Thus, as shown in FIG. 2C, there is eliminated the natural oxide film 6 by physical etching due to inert gas such as argon and so forth or reactive etching such as BCl₃ and so forth under atmosphere of reduced pressure or a few existence of oxygen. In succession, as shown in FIG. 2D, there is formed high quality aluminum oxide film 6a on the side wall of the Al-wiring, while introducing oxygen or oxygen radical in a state of not breaking a vacuum. As shown in FIG. 2E, there is formed a fluorine contained interlayer insulating film 7 on a barrier of high quality aluminum oxide film 6a.

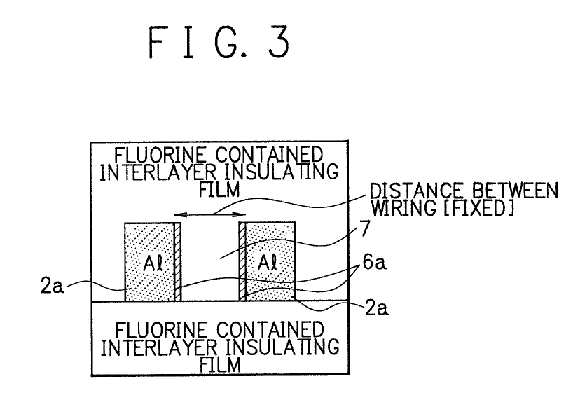

Next, there will be described film thickness of the aluminum oxide film 6a to be formed. Calculation of change of capacitance between adjacent Al-wiring in a model as shown in FIG. 3 is implemented. The Al-wiring 2a is fixed in distance between wiring in the state that the Al-wiring 2a is covered by uniform interlayer insulating film 7. Change of capacitance between Al-wiring according to film thickness of aluminum oxide film (relative dielectric constant 7.8) is compared with the case using ordinary silicon oxide film (relative dielectric constant 4.0).

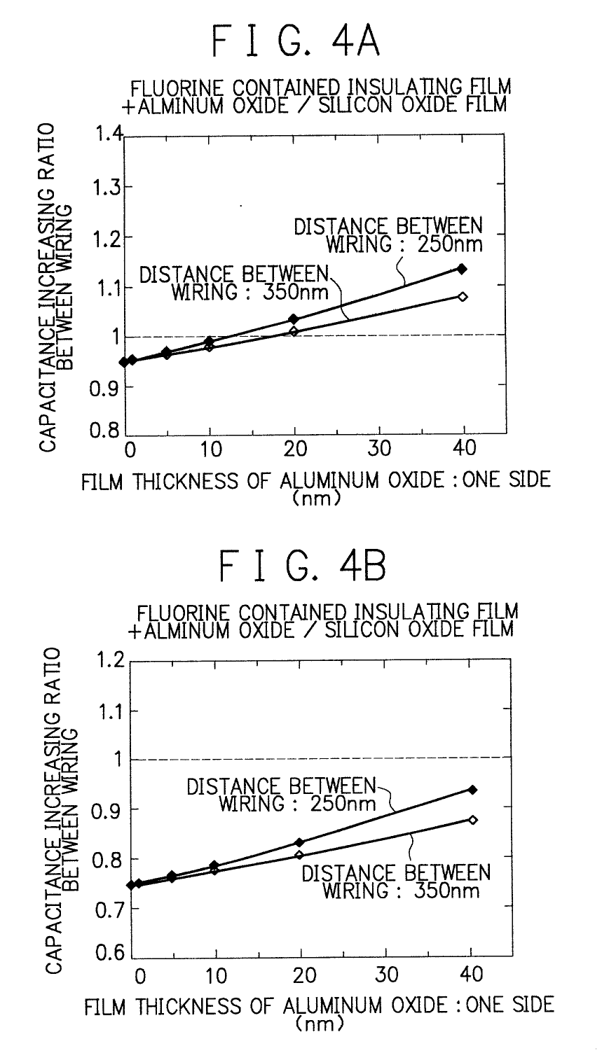

FIG. 4A shows comparison result of the case where distance between the wiring is 250 nm and 350 nm using fluorine contained insulating film with relative dielectric constant 3.8. According to the matter, it is understood that it is capable of being reduced the capacitance between wiring, rather than the case where ordinary oxide film is used, if the film thickness of the aluminum oxide film 6a is less than 10 nm. Further, FIG. 4B shows comparison result of the case where distance between the wiring is 250 nm and 350 nm using fluorine contained interlayer insulating film 7 with relative dielectric constant 3.0. In this case, it is capable of being reduced the capacitance between wiring even though film thickness of aluminum oxide film 6a is 40 nm.

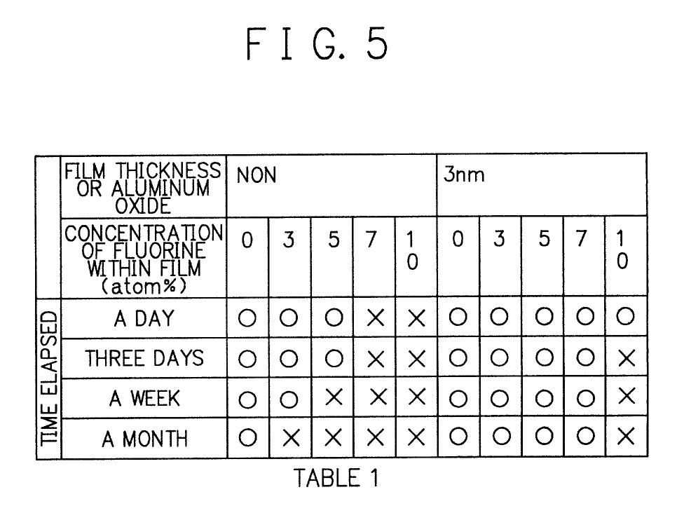

Next, there will be described relationship between fluorine concentration and wiring reliability. FIG. 5 is a table 1 showing result of PCT reliability examination in the case where there is changed fluorine concentration from 0 atom % to 10 atom %.

The PCT reliability examination is implemented under the condition that when aluminum oxide film 6a is newly formed in the thickness of 3 nm in 125° C., 100% RH, 2.5 Kgf/cm² while when no aluminum oxide film is formed in 125° C., 100% RH, 2.5 Kgf/cm². When the aluminum oxide film 6a is not formed, corrosion of the Al-wiring is observed in 3 atom % of fluorine concentration. To the contrary, when the aluminum oxide film 6a is formed in the thickness of 3 nm, corrosion of the Al-wiring is not observed in the fluorine concentration of less than 10 atom %. Ordinarily, fluorine concentration is necessary to prepare degree of approximately 5 atom % in order to achieve relative dielectric constant of 3.8 using fluorine contained oxide film. However, in the thickness of aluminum oxide film less than 3 nm, there is observed corrosion of the Al-wiring in the same PCT examination.

From the matter described above, it is appropriate that there is formed the aluminum oxide film 6a in the region of 3 nm to 10 nm, in which the relative dielectric constant is capable of being lowered in comparison with the silicon oxide, and there can be ensured corrosion-resistant to fluorine concentration less than 10 atom %.

Next, there will be described the first embodiment of the present invention in further detail using FIGS. 2A to 2E. As shown in FIG. 2A, there is formed Aluminum 2 (in some cases copper is contained) on a silicon substrate 1 having insulating film 8 at the face on which elements such as transistors and so forth (not illustrated) are formed, in the thickness of 300 nm to 800 nm by the sputtering method. The Aluminum 2 has contact layer such as TiN/Ti3 and so forth in order to contact with elements of under layer and so forth at the under layer, in the thickness of 30 nm to 200 nm. Further, at the upper portion, there is formed reflection avoidance film of TiN4 and so forth for avoiding reflection at the time of lithography processing, in the thickness of 10 nm to 100 nm. There is formed a photoresist mask 5 which is subjected to patterning by photolithography method on these metallic film.

As shown in FIG. 2B, there is formed the Al-wiring 2a, while performing etching the Aluminum 2 by chlorine gas and so forth, with a photoresist being subjected patterning as a mask. When it causes the Al-wiring 2a to be etching using photoresist mask, there is formed a natural oxide film in which carbon as being constituent atom of the photoresist, or chlorine and so forth within gas used for etching.

Subsequently, as shown in FIG. 2C, there is eliminated the natural oxide film 6 containing carbon or chlorine and so forth after elimination of photoresist 5a remaining in the Al-wiring 2a by using oxide plasma and wet parting agent. By way of elimination process of the natural oxide film 6, there is eliminated the natural oxide film 6 formed on the side wall of the Al-wiring 2a by physical sputtering due to plasma such as argon and so forth or reactive etching due to gasses such as BCl₃ and so forth under atmosphere of reduced pressure less than 1 mTorr or a few existence of oxygen such as oxygen concentration less than 1 vol %.

As shown in FIG. 2D, there is formed high quality aluminum oxide film 6a on the side wall of the Al-wiring 2a in the thickness of 3 nm to 10nm, while introducing oxygen or oxygen radical, ozone or oxygen plasma in a state of not breaking a vacuum continuously. Formation of the aluminum oxide film 6a is implemented under the temperature from 50° C. to 300° C.

In succession, as shown in FIG. 2E, there are formed a fluorine contained silicon oxide film containing fluorine with 1% to 9%, a fluorine and carbon contained silicon oxide film, a fluorine contained organic resin, and fluorine polyimide by a plasma CVD method, a thermal CVD method or an application method by way of an interlayer insulating film.

There will be described operation of the present embodiment. A high quality aluminum oxide film 6a is formed at a portion where the Al-wiring 2a is contacted with an interlayer insulating film 7 containing fluorine. Thereby, it is prevented that the Al-wiring 2a is corroded by the fluorine. There is eliminated the natural oxide film 6 which contains impurities such as chlorine and so forth formed at the time of Al-etching. There is newly formed high quality aluminum oxide film 6a. Thereby, it becomes possible to prevent corrosion of the Al-wiring 2a with respect to the interlayer insulating film 7 containing fluorine of fluorine concentration less than 10 atom %. Further, when there is used the interlayer insulating film 7 of relative dielectric constant less than 3.8, it is capable of being reduced the relative dielectric constant in comparison with the case where there is used silicon oxide film (relative dielectric constant 4.0) by the fact that film thickness of aluminum oxide film 6a is made up to less than 10 nm in the space between wiring with 0.25 μm.

Consequently, according to the first embodiment of the present invention, it is capable of preventing that the Aluminum 2 is corroded by fluorine even though the Al-wiring 2a is contacted with the interlayer insulating film containing fluorine directly. It is capable of being reduced the relative dielectric constant in comparison with the case where there is used the silicon oxide film for the interlayer insulating film by the fact that film thickness of the aluminum oxide film is made up to less than 10 nm.

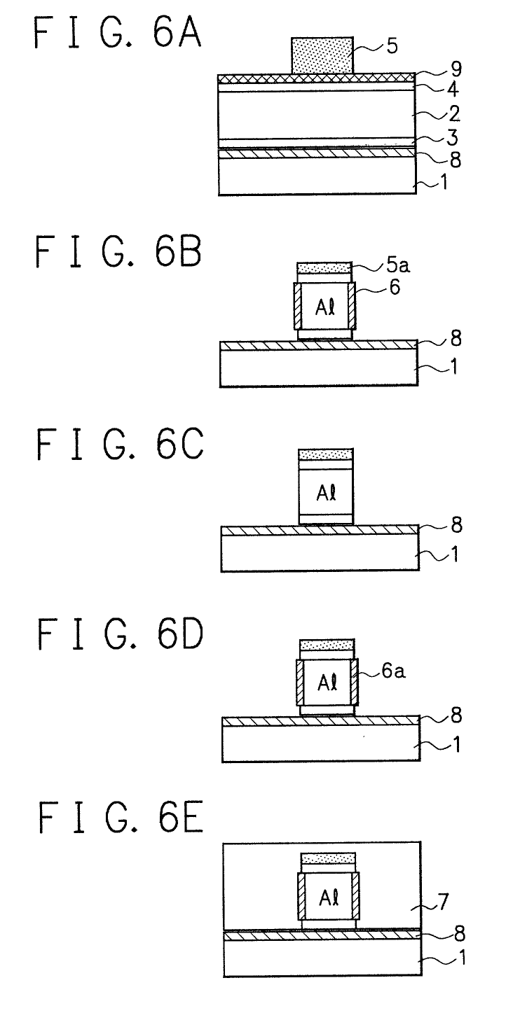

There will be described a second embodiment of the present invention in detail referring to FIGS. 6A to 6E. There is formed Aluminum 2 (in some cases copper is contained) on a silicon substrate 1 having insulating film 8 at the face on which elements such as transistors and so forth (not illustrated) are formed, in the thickness of 300 nm to 800 nm by the sputtering method. The Aluminum 2 has contact layer such as TiN/Ti3 and so forth in order to contact with elements of under layer and so forth at the under layer, in the thickness of 30 nm to 200 nm. Further, at the upper portion, there is formed reflection avoidance film of TiN4 and so forth for avoiding reflection at the time of lithography processing, in the thickness of 10 nm to 100 nm. Further, upper portion thereof, there is formed a silicon oxide film 9 in the thickness of 100 nm to 300 nm which is used by way of hard mask at the time of etching.

As shown in FIG. 6A, there is formed a photoresist mask 5 which is given in such a way that patterning is performed by a lithography method on these silicon oxide film 9. The silicon oxide film 9 is etched by gas of fluorine system through a photoresist given a patterning. The Al-wiring 2a is formed, while etching the Aluminum 2 by chlorine gas and so forth with the silicon oxide film 9 being subjected to patterning as the hard mask. More minuter wiring treatment becomes possible, because with respect to the Aluminum 2, etching selection ratio of the silicon oxide film 9 is higher than that of the photoresist. Furthermore, adjustment of taper angle (slope of wiring side wall) is easier than the photoresist mask, therefore, it becomes advantageous for the sake of elimination process of the natural oxide film of the next manufacturing process. Moreover, there is a merit that the TiN film and so forth on the Al-wiring do not undergo damage in the process for eliminating the natural oxide film 6 or in the process for forming the aluminum oxide film.

Next, as shown in FIG. 6B, when there is implemented the Al-wiring 2a using the mask of the silicon oxide film 9, there is formed the natural oxide film 6 containing Si within the silicon oxide film or chlorine within gas used in etching or the like. As shown in FIG. 6C, there is eliminated the natural oxide film 6 containing Si or chlorine and so forth. By way of elimination process of the natural oxide film 6, there is eliminated the natural oxide film 6 formed on the side wall of the Al-wiring 2a by physical sputtering due to plasma such as argon and so forth or reactive etching due to gasses such as BCl₃ and so forth under atmosphere of reduced pressure less than 1 mTorr or a few existence of oxygen such as oxygen concentration less than 1 vol %. It is capable of being eliminated the natural oxide film 6 advantageously if the Al-wiring 2a has some taper at the time of etching by the silicon oxide film 9.

Continuously, as shown in FIG. 6D, there is formed high quality aluminum oxide film 6a on the side wall of the Al-wiring 2a in the thickness of 3 nm to 10 nm, while introducing oxygen or oxygen radical, ozone or oxygen plasma in a state of not breaking a vacuum continuously. Formation of the aluminum oxide film 6a is implemented under the temperature from 50° C. to 300° C.

In succession, as shown in FIG. 6E, there are formed a fluorine contained silicon oxide film containing fluorine with 1% to 9%, a fluorine and carbon contained silicon oxide film, a fluorine contained organic resin, and fluorine polyimide by a plasma CVD method, a thermal CVD method or an application method by way of an interlayer insulating film.

There will be described operation of the present second embodiment. A high quality aluminum oxide film 6a is formed at a portion where the Al-wiring 2a is contacted with an interlayer insulating film 7 containing fluorine directly. Thereby, it is prevented that the Al-wiring 2a is corroded by the fluorine. The Al-wiring 2a is etched by using the hard mask by the silicon oxide film 9. There is eliminated the natural oxide film 6 which contains impurities such as Si, chlorine and so forth formed at the time of the above etching. There is newly formed high quality aluminum oxide film 6a. Thereby, it becomes possible to prevent corrosion of the Al-wiring 2a with respect to the interlayer insulating film 7 containing fluorine of fluorine concentration less than 10 atom %. Further, when there is used the interlayer insulating film 7 of relative dielectric constant less than 3.8, it is capable of being reduced the relative dielectric constant in comparison with the case where there is used silicon oxide film (relative dielectric constant 4.0) by the fact that film thickness of aluminum oxide film 6a is made up to less than 10 nm in the space between wiring with 0.25 μm.

Further, since the etching of the Aluminum 2 is implemented with the hard mask made from the silicon oxide film 9, the wiring can have a tapered shape, thus elimination of the natural oxide film 6 becomes easy. Furthermore, there is the merit that the TiN film and so forth on the Al-wiring 2a do not undergo damage in the process for eliminating the natural oxide film 6 or in the process for forming the aluminum oxide film 6a.

Consequently, according to the second embodiment of the present invention, it is capable of preventing that the Aluminum 2 is corroded by fluorine even though the Al-wiring 2a is contacted with the interlayer insulating film 7 containing fluorine directly. It is capable of being reduced the relative dielectric constant in comparison with the case where there is used the silicon oxide film for the sake of interlayer insulating film 7 by the fact that film thickness of the aluminum oxide film 6a is made up to less than 10 nm. Further, when the hard mask of the silicon oxide film 9 is used, the Al-wiring 2a can have tapered shape. Not only it is capable of being eliminated the natural oxide film 6 containing impurities formed at the time of Al-etching in the next process easily, but there is the merit that the TiN film and so forth on the Al-wiring 2a do not undergo damage.

As described above, according to the present invention, it is capable of being prevented that Aluminum is corroded by fluorine even though the Al-wiring is contacted with the interlayer insulating film containing fluorine directly.

Furthermore, It is capable of being reduced the relative dielectric constant in comparison with the case where there is used the silicon oxide film for the sake of interlayer insulating film by the fact that film thickness of the aluminum oxide film is made up to less than 3 nm to 10 nm.

Moreover, when the hard mask of the silicon oxide film is used, the Al-wiring can have tapered shape. Not only it is capable of being eliminated the natural oxide film containing impurities formed at the time of Al-etching in the next process easily, but there is the merit that the TiN film and so forth on the Al-wiring do not undergo damage.

While preferred embodiments of the invention have been described using specific terms, the description has been for illustrative purpose only, and it is to be understood that changes and variations may be made without departing from the spirit or scope of the following claims.

What is claimed is:

1. A semiconductor device using metal in which aluminum is regarded to be main component for the sake of wiring, and using fluorine contained insulating film for the sake of interlayer insulating film, wherein a portion of said wiring which is contacted with said fluorine contained insulating film is covered with aluminum oxide film.

2. A semiconductor device as claimed in claim 1, wherein film thickness of said aluminum oxide film is thickened more than 3 nm and film thickness of said aluminum oxide is thinned less than 10 nm.

3. A semiconductor device as claimed in claim 1, wherein there is used any one of a fluorine contained silicon oxide film, fluorine contained carbon resin, fluorine contained silicon carbon resin, and fluorine polyimide within which fluorine of fluorine concentration less than 10 atom % is contained by way of said fluorine contained insulating film.

4. A manufacturing method of a semiconductor device comprising the processes of:
a process for providing metal whose main component is aluminum on semiconductor substrate;
a process for forming wiring, while etching said metal;
a process for eliminating natural oxide film which is formed on side wall of said wiring;
a process for forming aluminum oxide film on said side wall of said wiring from which said natural oxide film is eliminated; and
a process for forming interlayer insulating film in which fluorine contained insulating film is used.

5. A manufacturing method of a semiconductor device comprising the processes of:
a process for providing metal whose main component is aluminum on semiconductor substrate;
a process for etching silicon oxide film, while forming said silicon oxide film on said metal;
a process for forming wiring, while etching said metal with said etched silicon oxide film as a mask;
a process for eliminating natural oxide film which is formed on side wall of said wiring;
a process for forming aluminum oxide film on said side wall of said wiring from which said natural oxide film is eliminated; and
a process for forming interlayer insulating film using fluorine contained insulating film.

6. A manufacturing method of a semiconductor device as claimed in claim 4, wherein, by way of eliminating method of said natural oxide film and forming method of said aluminum oxide film, said eliminating method eliminates natural oxide film from surface of said metal by plasma from inert gas such as argon and so forth at reduced pressure, before said forming method implements plasma processing, while introducing gas containing either oxygen or ozone, thus forming said aluminum oxide film with uniform film property.

7. A manufacturing method of a semiconductor device as claimed in claim 5, wherein, by way of eliminating method of said natural oxide film and forming method of said aluminum oxide film, said eliminating method eliminates natural oxide film from surface of said metal by plasma from inert gas such as argon and so forth at reduced pressure, before said forming method implements plasma processing, while introducing gas containing either oxygen or ozone, thus forming said aluminum oxide film with uniform film property.

8. A manufacturing method of a semiconductor device as claimed in claim 4, wherein film thickness of said aluminum oxide film is thickened more than 3 nm and film thickness of said aluminum oxide is thinned less than 10 nm.

9. A manufacturing method of a semiconductor device as claimed in claim 5, wherein film thickness of said aluminum oxide film is thickened more than 3 nm and film thickness of said aluminum oxide is thinned less than 10 nm.

10. A manufacturing method of a semiconductor device as claimed in claim 4, wherein there is used any one of a fluorine contained silicon oxide film, fluorine contained carbon resin, fluorine contained silicon carbon resin, and fluorine polyimide within which fluorine of fluorine concentration less than 10 atom % is contained by way of said fluorine contained insulating film.

11. A manufacturing method of a semiconductor device as claimed in claim 5, wherein there is used any one of a fluorine contained silicon oxide film, fluorine contained carbon resin, fluorine contained silicon carbon resin, and fluorine polyimide within which fluorine of fluorine concentration less than 10 atom % is contained by way of said fluorine contained insulating film.
